(19) United States
(12) Patent Application Publication
(10) Pub. No.: US 2006/0282727 A1
(43) Pub. Date: Dec. 14, 2006

(54) Scan test design method, scan test circuit, scan test circuit insertion cad program, large-scale integrated circuit and mobile digital equipment

(76) Inventor: Masahiro Hoshaku, Hyogo (JP)

Correspondence Address: PANASONIC PATENT CENTER;c/o MCDERMOTT WILL & EMERY LLP, 600 13TH STREET, NW, WASHINGTON, DC, 20005-3096, US

(21) Appl. No.: 10/557,021

(22) PCT Filed: Jul. 8, 2004
(86) PCT No.: PCT/JP04/10089

§ 371 Date: Nov. 16, 2005

(30) Foreign Application Priority Data
Jul. 9, 2003 (JP) 2003-272403

(51) Int. Cl. G01R 31/28

(52) U.S. Cl. 714/726

(57) ABSTRACT

In scan test circuit design, a plurality of flipflop circuits (102a, 102b or 102c) driven with each of final-stage elements 101f of a clock tree T are connected in series, to form a sub-scan chain. Also, sub-scan chains smallest in the relative difference in the number of stages of delay elements existing from the clock supply point S of the clock tree T (i.e., sub-scan chains different by one stage) are connected to each other. Further, sub-scan chains are connected so that data shift be made from a flipflop circuit larger in clock delay to a flipflop circuit smaller in clock delay. This reduces the number of delay elements inserted in data lines of a shift register for hold time guarantee in shift operation of the scan shift register, and suppresses power consumption.

### TECHNICAL FIELD

The present invention relates to an LSI design method, an LSI test circuit and an LSI design CAD program. More particularly, the present invention relates to a design-for-testability technology that secures design guarantee on the hold time in the operation of a shift register that may cause a problem at the time of design of a scan test circuit and suppresses increase in circuit area, power consumption and leak current that may occur with insertion of hold guarantee delay elements.

### BACKGROUND ART

Conventionally, design for testability involves scan test design most commonly. The scan test design will be described with reference to FIG. 5.

Referring to FIG. 5, after RTL design, a logic synthesis CAD program 502 is executed for an RTL file 501 as input data to generate a gate-level netlist 503. Flipflop (FF) circuits constituting part of the resultant gate-level circuit 503 are first replaced with scan FF circuits under a scan test circuit insertion CAD program 504. Each of the scan FF circuits has normal data input terminal D and a test input terminal DT as its input terminals, so that data input via the DT terminal is selected if a scan shift mode is set, and data input via the D terminal is selected if a test mode (non-scan shift mode) is set. The scan test circuit insertion CAD program 504 then cascades an output terminal NQ (or Q) of a scan FF circuit to the test input terminal DT of another scan FF circuit. As a result, a plurality of cascaded scan FF circuits operate as a huge shift register, generating a scan test circuit inserted netlist 505.

In testing of the circuit, data for testing prepared with an automatic test pattern generation (ATPG) program is input in series into the scan shift register via an external scan-in terminal, to allow the data to shift in the shift register. The mode is then switched to the test mode to execute normal data transfer between the FF circuits. Thereafter, the shift register operation is again executed, to allow the data to be output via an external scan-out terminal. The output data is checked against an expected value to thereby perform LSI fault examination.

In the conventional scan test design described above, the connection between DT input terminals and Q output terminals of scan FF circuits is randomly determined. In other words, no specific designation is made in design on from which FF circuit to which FF circuit data should be shifted. As a result, a circuit obtained by the conventional scan design has a configuration as shown in FIG. 2, for example. In the example of FIG. 2, shift data transfer of FF circuit 202a→FF circuit 202b and even shift data transfer between different clock tree lines such as FF circuit 202b→FF circuit 202c→FF circuit 202d and circuit 202f→FF circuit 202g→FF circuit 202h occur in some portions.

In a circuit obtained by the conventional scan design described above, buffers for delay insertion are placed at predetermined positions to reduce clock skew, as described in Japanese Laid-Open Patent Publication No. 11-108999.

Problems to be Solved

In attaining operation guarantee for the scan shift register by the conventional design method described above, since shift data transfer between different clock tree lines occur in many places as exemplified in FIG. 2, a number of delay elements 206a to 206e for hold guarantee must be inserted in such scan shift circuit portions between different clock tree lines. This disadvantageously increases the circuit area, the power consumption and the leak current during standby of a number of delay elements.

Moreover, in the conventional circuit in which FF circuits of different clock tree lines are connected to each other, as in the example of FIG. 2, when design adopts a semiconductor microfabrication process, which is significantly susceptible to interference such as crosstalk and IR drop, the delay time in the clock tree portion will be affected by such interference and IR drop, resulting in further need for a hold margin in shift data transfer, and thus additional increase in the number of delay elements inserted in the scan shift circuit portion. This additional increase in the number of delay elements resulting from the design for testability described above will further increase the LSI circuit area and moreover lead to increase in power consumption and significant increase in leak current during standby of a number of delay elements.

### DISCLOSURE OF THE INVENTION

An object of the present invention is providing a scan test design method and a scan test circuit in which the number of delay elements inserted in a scan shift circuit is effectively reduced even under a conspicuous influence of crosstalk and IR drop that will occur significantly in a large-scale integrated circuit adopting a microfabrication process, to thereby ensure operation guarantee for a scan shift register while reducing the area of the large-scale integrated circuit and effectively suppressing the power consumption and the off-leak current.

To solve the problems described above, systematic examination was newly done on the connection relationship among a plurality of scan flipflop (FF) circuits, that is, on from which scan FF circuits to which scan FF circuits data should be transferred, to attain reduction in the number of delay elements to be inserted.

From the above examination, according to the present invention, a scan shift register is formed from a plurality of flipflop circuits driven with each of the final-stage elements of clock tree synthesis (CTS) as one group. A plurality of thus-formed scan shift registers, each serving as a sub-scan chain, may be connected to one another, to constitute a larger scan shift register. In such a case, the sub-scan chains are connected in the following priority order.

(1) Shift registers equal in the number of gate stages in the clock line are connected to each other.

(2) In connection of shift registers different in the number of stages, priority is given to connection between those smaller in the difference in the number of stages.

(3) In connection of shift registers different in the number of stages, connection is made so that data be transferred from a sub-chain larger in the number of stages toward a sub-chain smaller in the number of stages, or from a sub-chain larger in clock delay toward a sub-chain smaller in clock delay.

Specifically, the scan test design method of the present invention is a scan test design method in which in a semiconductor integrated circuit having a number of scan flipflop circuits as a scan test circuit, with a clock tree being formed for clock terminals of the scan flipflop circuits, attention is paid to a plurality of final-stage elements located at the final stage of the clock tree, and a plurality of scan flipflop circuits driven with each of the final-stage elements are connected in series, to form a scan shift register for each final-stage element.

In the scan test design method described above, the scan shift register for each of the final-stage elements is regarded as a sub-scan chain, and in connecting such sub-scan chains to each other to form a longer scan shift register, priority is given to connection between sub-scan chains equal in the number of stages of elements constituting the clock tree.

In the scan test design method described above, the scan shift register for each of the final-stage elements is regarded as a sub-scan chain, and in connecting such sub-scan chains to each other to form a longer scan shift register, priority is given to connection between sub-scan chains smallest in a relative difference in the number of stages of elements constituting the clock tree when sub-scan chains different in the number of stages of elements constituting the clock tree are to be connected to each other.

In the scan test design method described above, when sub-scan chains different in the number of stages of elements constituting the clock tree are connected to each other, a delay element of the number determined in advance according to the difference in the number of stages of elements constituting the clock tree is inserted between the sub-scan chains connected to each other.

In the scan test design method described above, the scan shift register for each of the final-stage elements is regarded as a sub-scan chain, and in connecting such sub-scan chains to each other to form a longer scan shift register, the sub-scan chains are connected so that data transfer be made from a sub-scan chain longer in a delay time from a clock origin point of the clock tree up to the clock terminals of the flipflop circuits constituting the sub-scan chain to a sub-scan chain shorter in the delay time.

Alternatively, the scan test design method of the present invention is a scan test design method in which in a semiconductor integrated circuit having a number of scan flipflop circuits as a scan test circuit, with a clock tree being formed for clock terminals of the scan flipflop circuits, the semiconductor integrated circuit also having a gated clock tree with clock gate elements placed at a plurality of predetermined positions of the clock tree, attention is paid to the plurality of clock gate elements, and a plurality of scan flipflops driven with each of the clock gate elements are connected in series, to form a scan shift register for each clock gate element.

In the scan test design method described above, the scan shift register for each of the final-stage elements is regarded as a sub-scan chain, and in connecting such sub-scan chains to each other to form a longer scan shift register, the scan test design method described above is executed.

The scan test circuit of the present invention includes a scan shift register having a plurality of scan flipflop circuits connected in series, with a clock tree being formed for clock terminals of the plurality of scan flipflop circuits, wherein at least two flipflop circuits equal in the number of stages of elements of the clock tree from a predetermined clock supply point of the clock tree up to the clock terminals of the flipflop circuits, among the plurality of scan flipflop circuits, are connected to each other sequentially, to form the scan shift register.

In the scan test circuit described above, as for flipflop circuits different in the number of stages of elements of the clock tree from the predetermined clock supply point of the clock tree up to the clock terminals of the flipflop circuits, flipflop circuits smallest in a relative difference in the number of stages of elements of the clock tree from the predetermined clock supply point of the clock tree up to the clock terminals of the flipflop circuits are connected to each other sequentially, to make the scan shift register longer.

Alternatively, the scan test circuit of the present invention has a plurality of scan flipflop circuits, with a clock tree being formed for clock terminals of the plurality of scan flipflop circuits, wherein for each of a plurality of final-stage elements located at the tail ends of the clock tree, a scan shift register is formed from a plurality of flipflop circuits connected to the final-stage element.

In the scan test circuit described above, delay elements are placed between the scan shift registers, and the scan shifter registers are connected to each other via the delay elements to form a long shift register.

In the scan test circuit described above, each of the delay circuits is composed of a transistor having a threshold voltage higher than a threshold voltage of transistors constituting the flipflop circuits.

The scan test circuit insertion CAD program of the present invention, for a semiconductor integrated circuit having a number of flipflop circuits, with a clock tree being formed for clock terminals of the flipflop circuits, allows a computer to execute the steps of: replacing the flipflop circuits with scan flipflop circuits; and connecting a plurality of flipflop circuits driven with each of a plurality of final-stage elements located at the final stage of the clock tree in series to form a scan shift register.

Alternatively, the scan test circuit insertion CAD program of the present invention allows a computer to execute the steps of: entering circuit data for a given scan test circuit having a plurality of scan flipflop circuits; temporarily cutting circuit connection in a shift data transfer portion between the scan flipflop circuits in the circuit data; thereafter, connecting in series a plurality of scan flipflop circuits driven with each of a plurality of final-stage elements located at the final stage of a clock tree, when such a clock tree is formed for clock terminals of the plurality of scan flipflop circuits, to form a scan shift register to thereby optimize a scan chain; and outputting netlist information after the optimization.

In the scan test circuit insertion program described above, when the scan shift register obtained by connecting a plurality of scan flipflop circuits driven with each of the final-stage elements in series is regarded as a sub-scan chain and such sub-scan chains different in the number of stages of elements constituting the clock tree are connected to each other, the program allows a computer to execute the steps of: giving priority to connection between sub-scan chains smallest in a relative difference in the number of stages of elements constituting the clock tree; and thereafter outputting netlist information.

The large-scale integrated circuit of the present invention includes: the scan test circuit described above; and an internal circuit to be tested by the scan test circuit.

The portable digital equipment of the present invention incorporates the large-scale integrated circuit described above.

As described above, according to the present invention, a scan shift register is formed from a plurality of flipflop circuits driven with each of the final-stage elements of the clock tree. Since these flipflop circuits have roughly the same propagation delay time of the clock signal to the flipflop circuits, design guarantee for the operation of the scan shift register can be easily obtained.

In the conventional method in which a position of occurrence of data hold violation cannot be specified at the time of insertion of a scan test circuit but only be specified later at the time of timing design, and a hold guarantee delay element is then inserted at the violation position, a number of hold guarantee delay elements must be inserted on the output side of the scan flipflop circuits. Therefore, such hold guarantee delay elements may make transition unnecessarily even during normal operation other than the scan test operation, disadvantageously causing increase in power consumption. According to the present invention, in which the number of hold guarantee delay elements inserted in the shift data transfer line can be reduced, low power can be realized. Moreover, since the leak current (off-leak current) during standby of the delay elements can be reduced, further low power can be realized.

In the conventional method in which hold guarantee delay elements are inserted after finding of hold violation as described above, even when the timing characteristic between flipflop circuits once satisfies the design constraints, the timing characteristic of the entire circuit may be deteriorated if hold violation occurs in the data shift circuit after insertion of the scan test circuit. According to the present invention, only the least number of hold guarantee delay elements can be inserted in the scan shift circuit, and also the circuit is configured to be less likely to cause hold violence at the subsequent timing design. Therefore, with little design reversion and improvement in the convergence of the timing characteristic, short-TAT design is permitted.

In carrying out of a fabrication test using the resultant scan test circuit, since it is possible to attain robust design that can guarantee scan shift operation satisfactorily even if a delay characteristic in the clock circuit occurs at a local position on the chip plane due to a variation in fabrication process, interference such as crosstalk, IR drop or the like, the fabrication yield at the scan test improves.

In particular, according to the present invention, in which the highest priority is given to connection of sub-scan chains equal in the number of stages of elements constituting the clock tree, and connection of sub-scan chains smallest in the relative difference in the number of stages of elements, design guarantee for the shift register operation of the scan test circuit can be obtained satisfactorily even if the propagation delay characteristic of the clock line varies locally due to a fabrication variation, interference such as crosstalk, or IR drop.

In addition, in the scan test circuit insertion CAD program of the present invention, which has a design algorithm of connecting a plurality of scan flipflop circuits driven with each of final-stage elements of the clock tree in series to form a scan shift register, insertion of the scan test circuit can be made automatically. Also, the design algorithm can be used at the same design stage as the conventional scan chain wiring optimization function. This makes it possible to design a semiconductor integrated circuit with no increase in the number of design stages and little design reversion.

Since the scan test circuit to be incorporated is a low-power circuit small in off-leak current and low in power consumption, digital equipment having a long battery life can be implemented by applying the present invention to battery-driven portable digital equipment and car-mounted digital equipment.

### BRIEF DESCRIPTION OF THE DRAWINGS

FIG. 1 is a view showing a scan test circuit having a configuration of a scan shift register in the first embodiment of the present invention.

FIG. 2 is a view showing a scan test circuit having a conventional scan shift register configuration.

FIG. 3 is a conceptual view showing a procedure of connecting sub-scan chains different in the number of stages of elements of a clock tree to each other in the fourth embodiment of the present invention.

FIG. 4 is a design flowchart demonstrating a scan test design method in the sixth and ninth embodiments of the present invention.

FIG. 5 is a conventional test design flowchart.

FIG. 6A is a view showing a distribution of clock skew in the sixth embodiment of the present invention, and FIG. 6B is a view showing a method of connection between sub-scan chains that have the clock skew distribution of FIG. 6A and are different in the number of stages of elements of a clock tree.

FIG. 7 is a view showing a configuration of a scan FF circuit in the seventh embodiment of the present invention.

FIG. 8 is a design flowchart demonstrating a method of scan chain connection using an inter-sub-scan chain clock delay distribution in the eighth embodiment of the present invention.

FIG. 9 is a flowchart showing details of test circuit insertion design in the design flowchart shown in FIG. 8.

FIG. 10 is a flowchart showing details of scan chain optimization in the design flowchart shown in FIG. 8.

FIG. 11 is a view illustrating the procedure of connection of sub-scan chains according to the flowchart of the test circuit insertion design in FIG. 9.

FIG. 12 is a view illustrating a procedure of connection of sub-scan chains according to the flowchart of the scan chain optimization design in FIG. 10.

FIG. 13 is a view showing a scan test circuit having a configuration of a scan shift register in the tenth embodiment of the present invention.

### BEST MODE FOR CARRYING OUT THE INVENTION

Hereinafter, embodiments of the present invention will be described with reference to the relevant drawings.

### First Embodiment

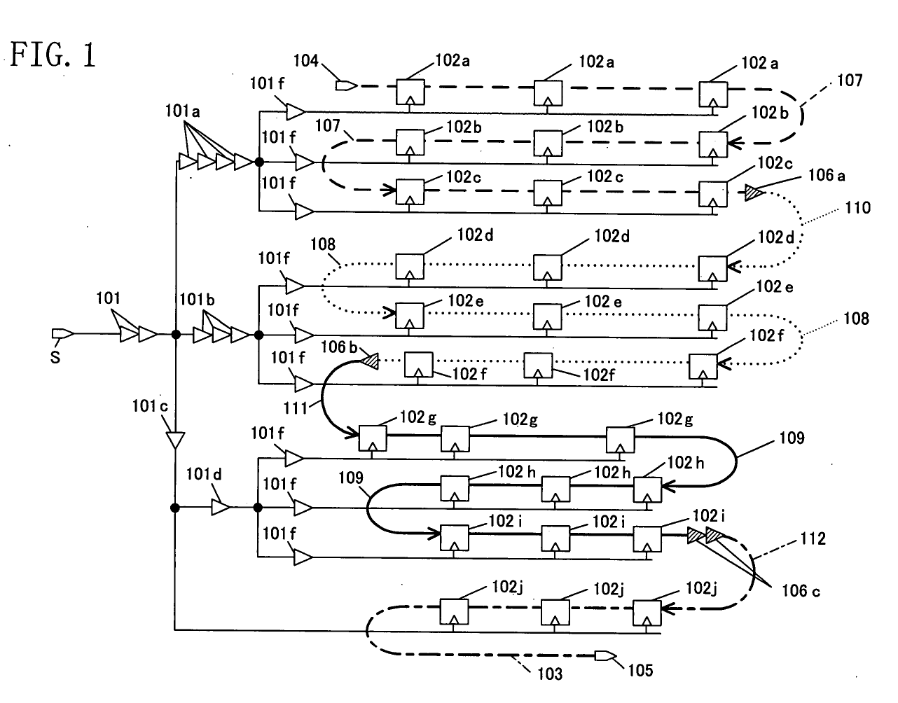

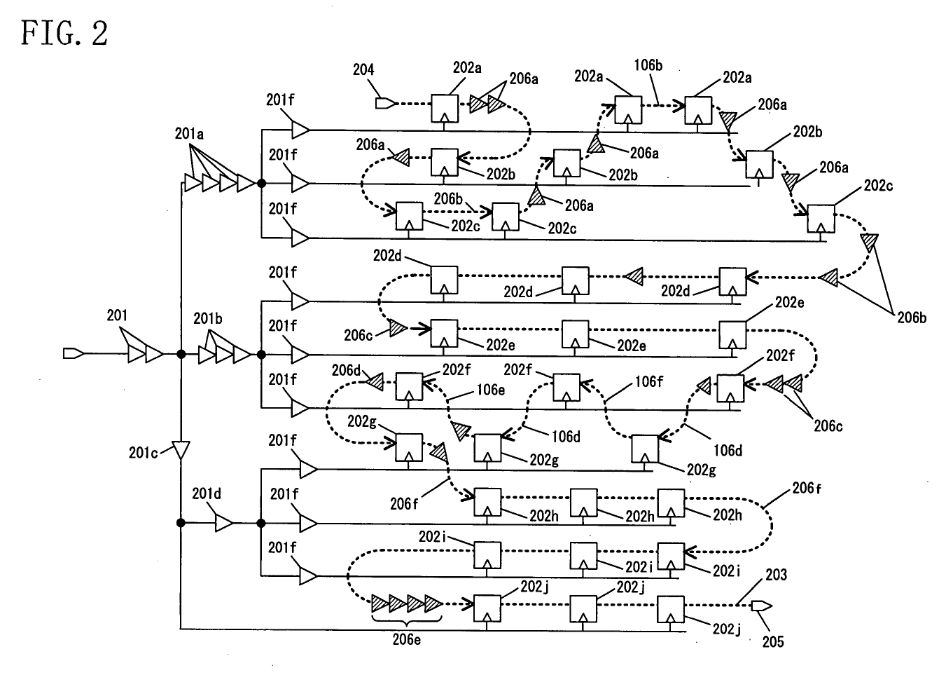

FIG. 1 shows a configuration of a scan shift register of a scan shift circuit implemented by a design-for-testability method of the first embodiment of the present invention, illustrating in particular the configuration of CTS buffers and the connection relationship in the scan shift register. This embodiment will be described with reference to FIG. 1.

Referring to FIG. 1, the reference numeral 101 denotes clock delay adjusting buffers and 101a to 101f denote CTS buffers. A clock tree T includes branching from a predetermined clock origin point or clock supply point S to the buffers 101a, 101b and 101c via the buffers 101, and each branch is further branched to three buffers 101f. A clock signal is supplied to clock terminals of a plurality of flipflop (FF) circuits 102a to 102j via the clock tree T.

In the design method of this embodiment, first, a scan shift register is formed from a plurality of FF circuits driven with each of the final-stage elements 101f of CTS as the minimum unit. In FIG. 1, therefore, the minimum unit of the scan shift register is formed using the three FF circuits 102a. Likewise, a scan shift register is formed by connecting in series the three FF circuits for each of the FF circuits 102b, 102c, 102d, 102e, 102f, 102g, 102h, 102i and 102j.

In this embodiment, the minimum unit of the scan shift register is called a sub-scan chain. The FF circuits in the sub-scan chain constitute an FF circuit group smallest in clock skew in view of the nature of CTS design. Therefore, stable shift operation is expected for such a scan shift register composed of FF circuits driven with the same CTS buffers.

In the event that the influence of interference such as crosstalk, IR drop and the like becomes conspicuous in a microfabrication process, a defect in data shift due to hold time violation in particular will cause a problem. A cause of this trouble is that the clock delay varies with crosstalk, IR drop and the like. In this embodiment, in which each sub-scan chain is a group of FF circuits driven with the same CTS buffers, such a variation of the clock delay affects these FF circuits roughly equally. Accordingly, a scan shift register ensuring stable operation guarantee against the influence of the delay variation described above can be provided.

### Second Embodiment

The second embodiment of the present invention will be described.

In FIG. 1 showing the first embodiment described above, a sub-scan chain was formed from the three FF circuits 102a. A scan shift register was also formed using the three FF circuits for each of the FF circuits 102b, 102c, 102d, 102e, 102f, 102g, 102h, 102i and 102j, as in the case of the three FF circuits 102a. In the first embodiment, therefore, a scan test circuit can be formed by connecting the inputs/outputs of the shift registers to scan inputs/outputs of the LSI. This configuration however requires a huge amount of test terminals in a large-scale circuit, causing increase in test cost and shortage of terminals due to limitations on the external terminals of the LSI. As a result, it may be difficult to implement the design for testability.

To solve the above problem, in this embodiment, the sub-scan chains described in the first embodiment are connected to each other to form a larger scan shift register, to thereby reduce the scan input/output terminals.

To state specifically, among the sub-scan chains described with reference to FIG. 1, the highest priority is given to connection between sub-scan chains equal in the number of stages of CTS buffers via an inter-sub-scan chain connection net 107, 108 or 109. In this connection between sub-scan chains, an arbitrary number of buffers may be inserted for hold time guarantee in consideration of the design margin. In particular, in the event that the clock delay varies in each sub-scan chain under the influence of interference such as crosstalk, IR drop and the like, the clock variation will be different between the sub-scan chains. Therefore, it is desirable to insert a hold guarantee buffer considering this variation. Note that the insertion of a buffer is not necessary required because in some cases the line length is sufficiently long in the connection between the sub-scan chains. In the circuit example of FIG. 1, insertion of a delay element for hold time guarantee can be omitted in the inter-sub-scan chain connection nets 107, 108 and 109. The FF circuits are therefore connected directly without intervention of such a delay element.

As described above, in this embodiment, the sub-scan chains equal in the number of stages of CTS buffer are connected to each other. This reduces the number of scan chains in the LSI, and thus can solve the problem of shortage of scan test terminals.

### Third Embodiment

The third embodiment of the present invention will be described.

The third embodiment is directed to a design method to be adopted when the number of scan test terminals (scan-in terminals and scan-out terminals) yet fails to fall within the limitation on the number of terminals even in the second embodiment described above.

When the limitation on the number of scan test terminals is not yet cleared in the second embodiment or when further reduction in the number of scan chains is desired for other reasons, it becomes necessary to connect scan shift registers different in the number of stages of CTS buffers to each other. In this case, as in the second embodiment, the first priority is given to connection of shift registers equal in the number of stages of CTS buffers in series via the inter-sub-scan chain connection net 107, 108 or 109.

Subsequently, the second priority is given to connection between shift registers smallest in the relative difference in the number of stages of buffers from the clock supply point S through the CTS buffers, that is, shift registers different by one stage in the number of stages, via a connection net 110 or 111. In FIG. 1, one delay element 106a or 106b is inserted in the connection net 110 or 111 because the difference in the number of stages is one.

When still further reduction in the number of scan shift chains is desired, the third priority is given to connection between sub-can chains different by up to two stages in the number of stages of CTS buffers via an inter-sub-scan chain connection net 112. In this case, two delay elements 106c are inserted in the connection net 112 because the difference in the number of stages is two. Thereafter, by use of a similar manner of giving higher priority to connection between shift registers smaller in the relative difference in the number of stages of CTS buffers, test design is performed to have scan shift chains of the number conforming to the design requirement specifications or design constraints. FIG. 1 shows an example of the scan test circuit configured by use of this method to finally give one scan chain 103. In the connection between sub-scan chains different in the number of stages of CTS buffers, a larger number of buffers are inserted in the connection portion larger in the relative difference in the number of stages, while a smaller number of buffers are inserted in the connection portion smaller in the relative difference in the number of stages. The number of buffers to be inserted should be determined in advance for each relative difference in the number of stages.

### Fourth Embodiment

The fourth embodiment of the present invention will be described.

In the second and third embodiments, the number of delay elements 106a to 106c to be inserted for hold time guarantee should be determined in advance in consideration of the design margin. In this regard, when sub-scan chains having a relative difference in the number of stages of CTS buffers among them and yet having various differences in the number of stages are directly connected to one another, as in the third embodiment in particular, over-margin design may possibly occur in the number of delay elements to be inserted in consideration of combination errors.

To solve the above problem, in the fourth embodiment, the following method is adopted. That is, the first priority is given to connection between shift registers equal in the number of stages of elements constituting the clock tree, as in the design method of the second embodiment described above. Thereafter, if further serial connection is necessary to provide a larger scan shift register, the following second priority, different from the second priority described in the third embodiment, is adopted.

That is, in the fourth embodiment, the following design method is adopted as the design rule for connecting sub-scan chains different in the number of elements of the clock circuit (for example, the number of CTS buffers) to each other. A sub-scan chain largest in the number of stages of CTS buffers is placed on the side of the scan-in terminal, while a scan shift register smallest in the number of stages of elements constituting the clock circuit is placed on the side of the scan-out terminal. Sub-scan chains connected between the sub-scan chain at the next stage on the side of the scan-in terminal and the sub-scan chain at the preceding stage on the side of the scan-out terminal are arranged in the descending order of the number of stages of CTS buffers from the side of the scan-in terminal toward the side of the scan-out terminal.

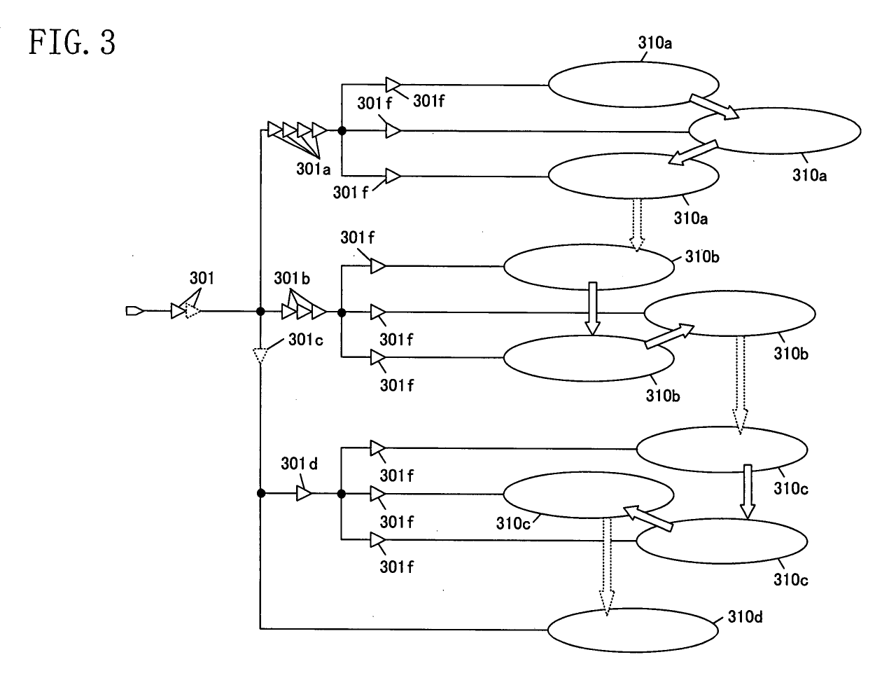

In other words, the scan test circuit configured by the design method described above is a scan test circuit conducting transfer between FF circuits equal in the number of stages of CTS buffers or shift operation from an FF circuit larger in the number of stages of CTS buffers toward an FF circuit smaller in the number of stages of CTS buffers (that is, in the order allowing data transfer from the side larger in the delay time of the supplied clock signal toward the side smaller in the delay time). To state specifically, in FIG. 3, the connection is first made between sub-scan chains 310a equal in the number of stages of CTS buffers, that is, seven stages, between sub-scan chains 310b equal in the number of stages of CTS buffers, that is, six stages, and between sub-scan chains 310c equal in the number of stages of CTS buffers, that is, five stages. Thereafter, the resultant sub-scan chains are connected together so that data transfer be made from the sub-scan chains 310a large in the number of stages of CTS buffers to the sub-scan chains 310b and to the sub-scan chains 310c smaller in the number of stages of CTS buffers, and then to a sub-scan chain 310d smallest in the number of stages of CTS buffers.

It is generally expected that a shift register large in the number of stages of CTS buffers is often slow in clock delay and a shift register small in the number of stages of CTS buffers is fast in clock delay. Therefore, in data transfer between sub-scan chains different in the number of stages of CTS buffer, data is transferred from an FF circuit slightly slow in clock delay to an FF circuit slightly fast in clock delay, and this results in reducing the margin of the setup time but ensuring safety design for the hold time. In a scan test circuit, in which no circuit is generally formed between FF circuits in the data shift circuit portion, there is enough room for the setup time. However, since no gate exists between FF circuits in the data shift circuit, a problem may arise in guarantee of the hold time in the scan shift register. In the fourth embodiment, a circuit configuration securing room for the hold time can be easily provided. Accordingly, in the fourth embodiment, a robust shift register against a variation in clock delay that may occur under the influence of interference such as crosstalk and IR drop can be obtained.

Moreover, in the fourth embodiment, because safety design is ensured against a variation in clock delay, no over-margin design is necessary for the number of delay elements for hold guarantee to be inserted in the data lines between sub-scan chains different in the number of stages of elements constituting the clock circuit, and thus the design precision increases. Therefore, the number of delay elements can be advantageously reduced compared with the conventional scan test circuit.

### Fifth Embodiment

The fifth embodiment of the present invention will be described.

In the second, third and fourth embodiments described above, since the number of delay elements inserted for hold guarantee can be reduced compared with the conventional scan test circuit, the circuit area can also be reduced. In the fifth embodiment, provided is a design method in which further increase in circuit area is suppressed.

Although the basic circuit design method is substantially the same as that in the second, third and fourth embodiments, for example, this embodiment has the following feature. In FIG. 1, for example, the delay elements 106a to 106c inserted in the inter-sub-scan chain connection nets 110 to 112 at the connections between the sub-scan chains are composed of transistors higher in threshold voltage than transistors constituting the FF circuits 102a to 102f and logic circuits. This permits attainment of a large delay time with a small number of delay elements. In other words, the fifth embodiment provides a method of forming the delay elements from high-threshold transistors compared with the threshold voltages of transistors constituting the entire LSI.

### Sixth Embodiment

The sixth embodiment of the present invention will be described.

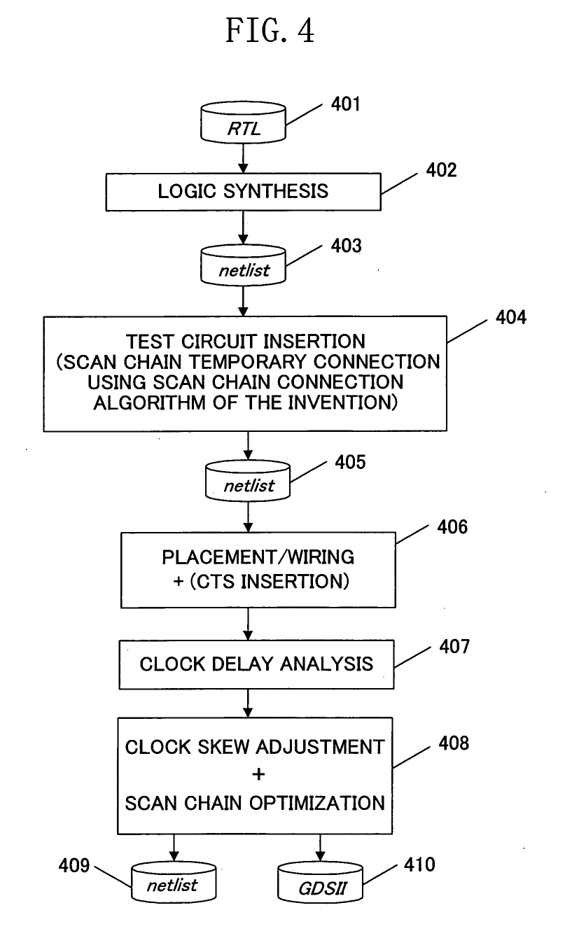

In the fourth embodiment described above, the order of connection among sub-scan chains was determined based on the number of stages of elements constituting the clock circuit. In the sixth embodiment, described is a design method in which the connection between scan chains is optimized in the process of adjusting the clock delay after the CTS insertion, to thereby provide a method of implementing a high-precision scan test circuit. The method will be described with reference to FIGS. 4, 5 and 6.

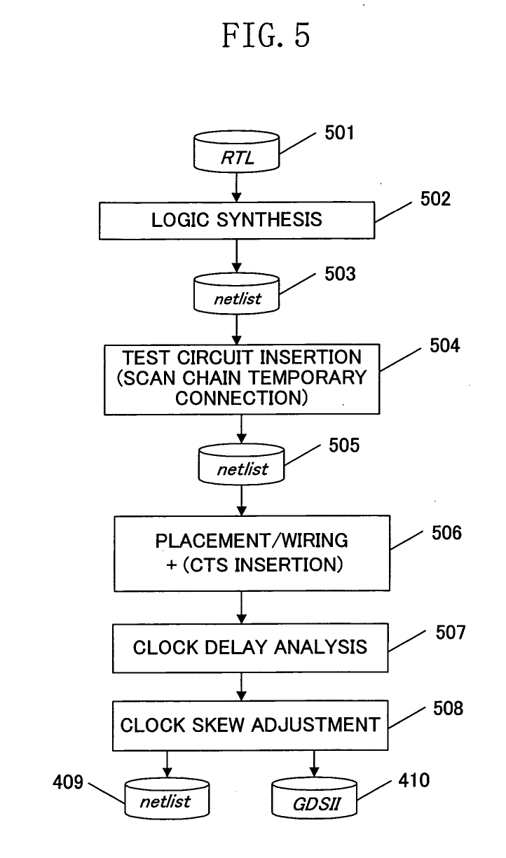

FIG. 5 shows a conventional general LSI design flow, and FIG. 4 shows a computer aided design (CAD) flow in the sixth embodiment. In the conventional design method, as shown in FIG. 5, after RTL design, the logic synthesis CAD program 502 is executed for the RTL file 501 as input data to generate the gate-level netlist 503. The scan test circuit insertion CAD program 504 is then executed for the gate-level netlist 503 to generate the scan test circuit inserted netlist 505.

The scan test circuit inserted netlist 505 is used as input data for a mask layout CAD program 506. Placement/wiring and then CTS insertion are performed under the mask layout CAD program 506, and then clock delay analysis is performed under a clock delay analysis program 507. Clock skew adjustment 508 is then performed using the analysis results, to output a netlist 409 and pattern information GDSII.

FIG. 4 shows an LSI design flow in the sixth embodiment. Referring to FIG. 4, the process is substantially the same until the clock delay analysis 407 (or 507) as that of the flow of FIG. 5 described above, except for the scan test circuit insertion program 404. The flow in this embodiment is different from the flow of FIG. 5 largely in the following two points. First, a scan test circuit inserted netlist 405 is generated by the scan chain design method described in the first to fourth embodiments (or also in the fifth embodiment) under the scan test circuit insertion CAD program 404. Second, optimization of the scan chain is also done with the algorithm described in the fourth embodiment in step 408 of adjusting clock skew using the results of the clock delay analysis 407.

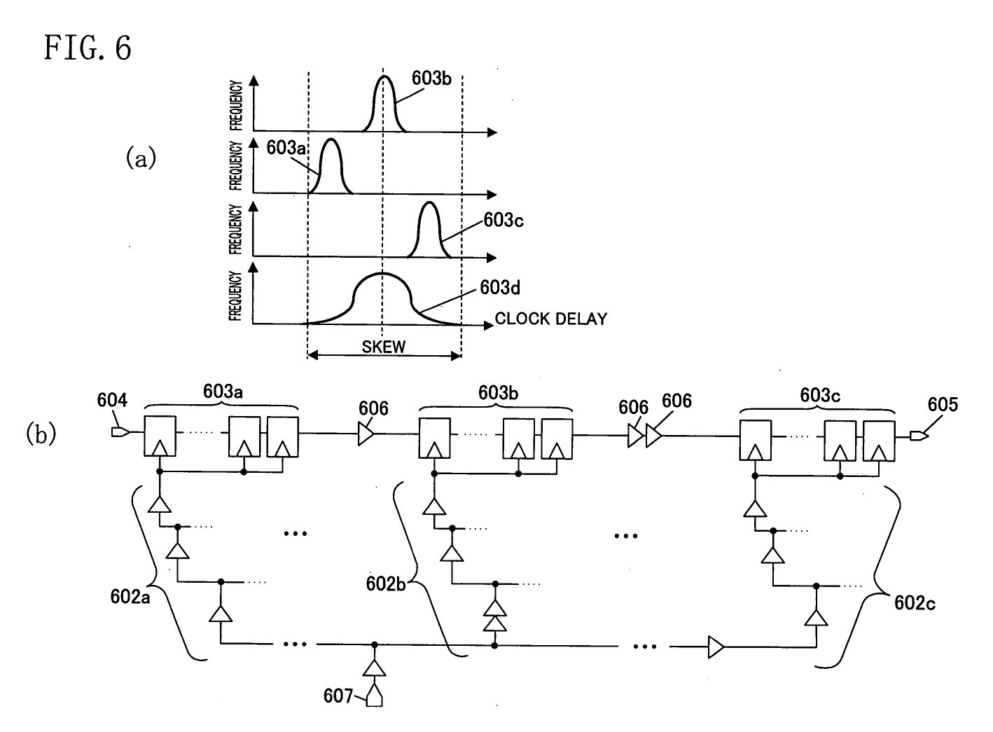

The scan chain optimization in the step 408 in the LSI design flow shown in FIG. 4 will be described with reference to FIG. 6.

In the clock delay analysis step 407 in FIG. 4, the clock delay in each sub-scan chain can be grasped, and based on this information, the clock delay difference between sub-scan chains is determined. An example of distribution of clock delays determined in the clock delay analysis step 407 is shown in FIG. 6A as a frequency distribution 603d. In FIG. 6A, three sub-scan chains 603a, 603b and 603c shown in FIG. 6B are exemplified among a number of sub-scan chains. Clock tree buffers 602a, 602b and 602c are respectively provided for FF circuits constituting the three sub-scan chains 603a, 603b and 603c, forming a CTS circuit. Frequency distributions 603a to 603c in FIG. 6A respectively correspond to the clock delay frequency distributions of the sub-scan chains 603a to 603c.

In the sixth embodiment, the input of the sub-scan chain 603a largest in clock delay distribution is connected to a scan-in terminal 604, while the output of the sub-scan chain 603c smallest in clock delay distribution is connected to a scan-out terminal 605. Also, connection of sub-scan chains inside the LSI is done so that the sub-scan chains are rearranged in the descending order of the center value of the clock delay distribution. In other words, in this embodiment, the sub-scan chain 603b middle in clock delay distribution is placed between the sub-scan chains 603a and 603c. Note that the re-connection is done with insertion of delay elements 606 for hold time guarantee.

Thus, in this embodiment, robust design against a variation in clock delay can be attained comparatively easily. Also, it is no more necessary to insert a number of delay elements for hold guarantee later indiscriminately, unlike the conventional scan design method. Accordingly, in the sixth embodiment, a scan test circuit permitting guarantee of scan shift operation with a considerably small number of delay elements, compared with the conventional design method, can be provided.

### Seventh Embodiment

In general, a scan test circuit includes no logic circuit between FF circuits in the scan shift circuit portion in many cases. Therefore, while a shift register has enough room in design limitations on the setup time, it has extremely little room in design limitations on the hold time in many cases. In the conventional scan test design, therefore, most commonly adopted is a method in which design guarantee on the hold time is secured by inserting buffers for hold guarantee in the data line in the scan shift-side circuit.

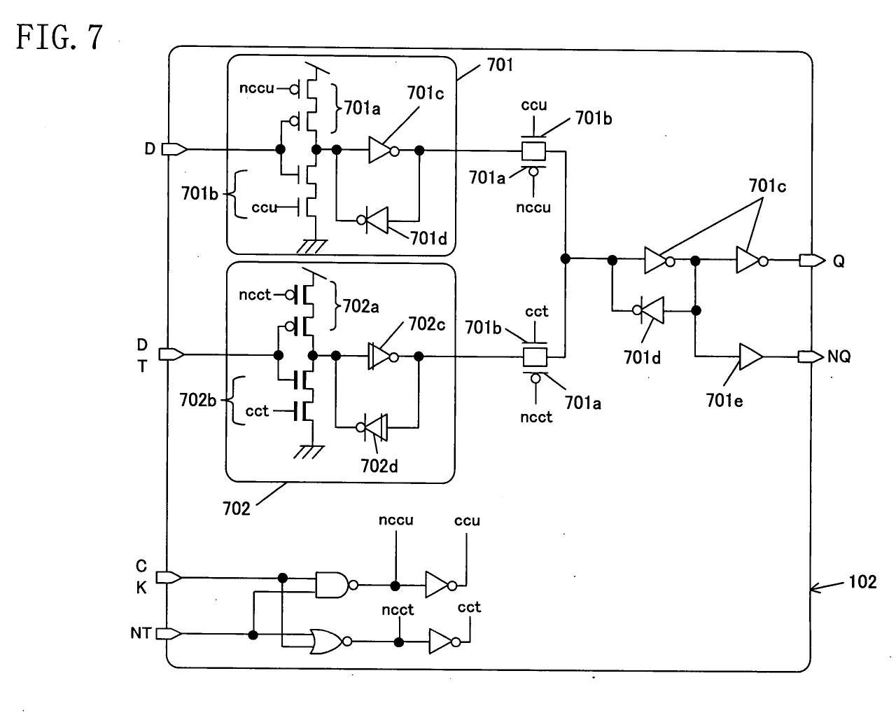

In the seventh embodiment of the present invention, provided are scan FF circuits that are unaffected by the setup time for data transfer between FF circuits in a normal circuit and do not cause increase in circuit area due to insertion of buffers for hold guarantee and the like. This embodiment will be described with reference to FIG. 7.

FIG. 7 shows an example of an FF circuit in the seventh embodiment. Referring to FIG. 7, a scan FF circuit 102 has a normal data input terminal D, a scan shift data input terminal DT, a clock terminal CK and a test mode terminal NT as the input terminals, and a pair of output terminals Q and NQ.

P-type transistors 702a, N-type transistors 702b, an inverter 702c and a tri-state inverter 702d constituting a scan shift data input-side circuit 702 located at the scan shift data input terminal DT are formed of transistors high in threshold voltage compared with transistors in the other portion of the FF circuit 102, in particular, transistors of components 701a to 701d constituting a normal data input-side circuit 701 at the normal data input terminal D.

Accordingly, in the seventh embodiment, it is unnecessary to insert a delay circuit for hold time guarantee in the data line in the scan shift-side circuit, and thus the delay time on the scan shift data input side can be increased without increase in the area of the FF circuit.

As a result, since the number of delay elements inserted in the shift data lines for the scan FF circuits for hold guarantee at the time of scan shift design can be reduced, an LSI small in circuit area and power consumption can be provided.

### Eighth Embodiment

The eighth embodiment of the present invention will be described.

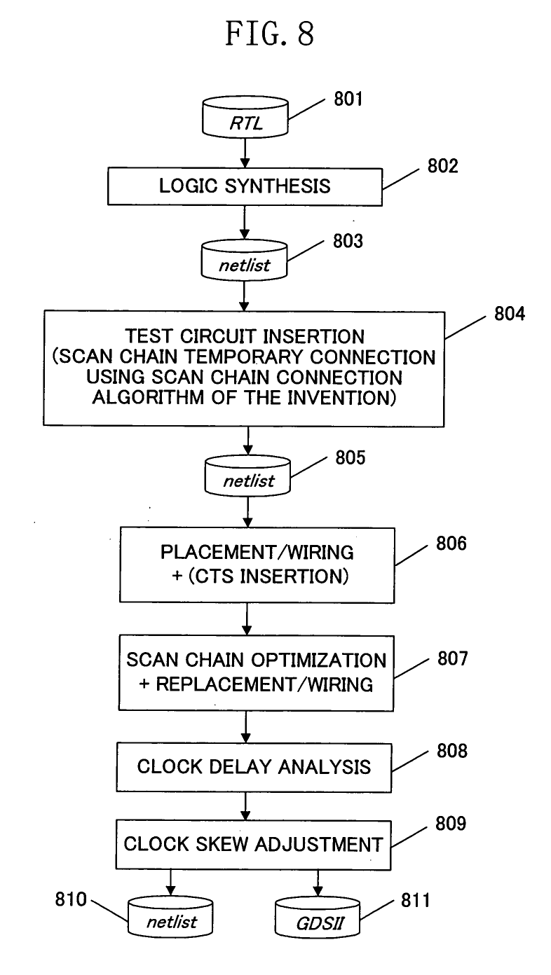

In the eighth embodiment, a design for testability (DFT) CAD program for executing the scan test design in the first to fourth and sixth embodiments will be described with reference to FIGS. 3 and 8.

In the scan insertion CAD program as a conventional DFT design program, FF circuits are replaced with scan FF circuits, and the shift data input terminal of a scan FF circuit is randomly scan-cascaded to an output terminal of another scan FF circuit.

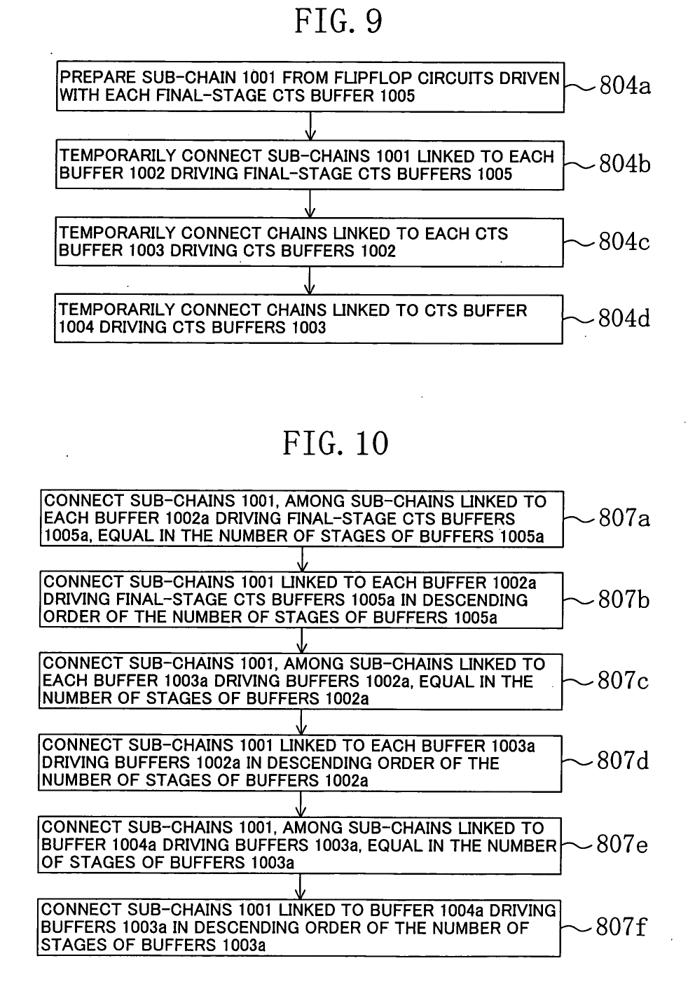

In a scan test circuit insertion CAD program in the eighth embodiment, as shown in FIG. 8, after RTL design, a logic synthesis CAD program 802 is executed for an RTL file 801 as input data to generate a gate-level netlist 803. A scan test circuit insertion CAD program 804 is then executed for the gate-level netlist 803 to generate a scan test circuit inserted netlist 805. FIG. 9 shows details of the scan test circuit insertion CAD program 804.

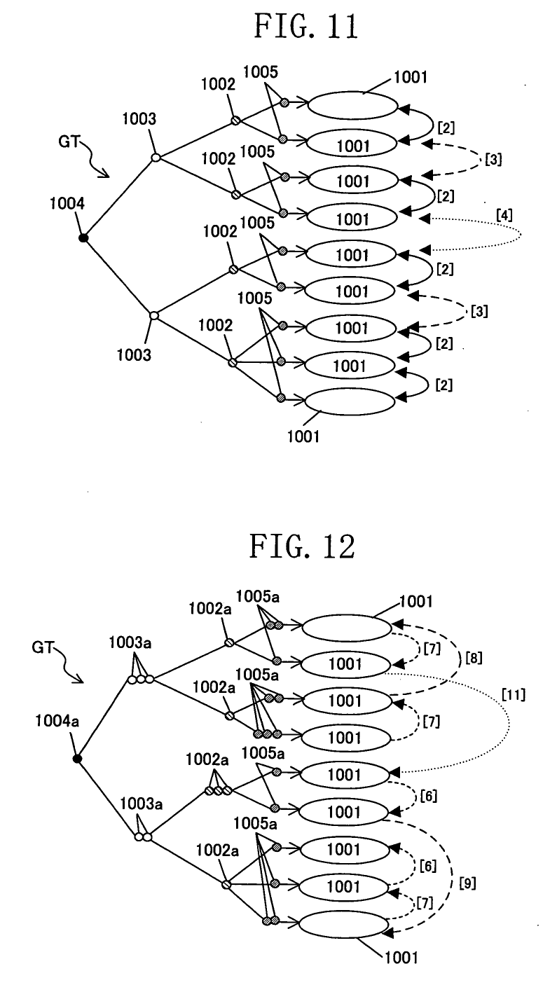

The scan test circuit insertion CAD program 804 of FIG. 9 will be described with reference to FIG. 11. First, in step 804a, a sub-scan chain 1001 is formed from FF circuits driven with each final-stage CTS buffer 1005. Thereafter, in step 804b, sub-scan chains 1001 linked to each of CTS buffers 1002 driving the final-stage buffers 1005 are temporarily connected to each other (shown by [2] in FIG. 11). In step 804c, sub-scan chains 1001 linked to each of a plurality of CTS buffers 1003 driving the CTS buffers 1002 are temporarily connected to each other (shown by [3] in FIG. 11). Finally, in step 804d, sub-scan chains 1001 linked to a first-stage CTS buffer 1004 driving the CTS buffers 1003 are temporarily connected to each other (shown by [4] in FIG. 11).

Referring back to FIG. 8, in the step 806, placement/wiring and then CTS insertion are performed under the mask layout CAD program.

Subsequently, in step 807, circuit information on the portion of shift data transfer between FF circuits constituting the scan shift register is temporarily cut, and netlist information on part of the scan shift register is reset. Thereafter, a netlist is reconfigured with the algorithm described in the first to sixth embodiments based on the number of stages of CTS buffers and the number of stages of elements of the clock circuit. A CAD program for reconfiguring the netlist is shown in FIG. 10. Using the new gate-level netlist in which the scan shift register-side circuit has been optimized, re-layout (relocation/wiring) or only wiring is performed.

The netlist reconfiguration program of FIG. 10 will be described with reference to FIG. 12. Referring to FIG. 10, first, in step 807a, sub-scan chains 1001, among the sub-scan chains 1001 linked to each of CTS buffers 1002a driving final-stage buffers 1005a, equal in the number of stages of CTS buffers 1005a are connected to each other (shown by [6] in FIG. 12). Thereafter, in step 807b, sub-scan chains 1001 linked to each CTS buffer 1002a driving final-stage buffers 1005a are connected to each other so that connection be made from a sub-scan chain 1001 larger in the number of stages of CTS buffers 1005a to a sub-scan chain 1001 smaller in the number of stages (shown by [7] in FIG. 12). In step 807c, sub-scan chains 1001, among the sub-scan chains 1001 linked to each CTS buffer 1003a driving a plurality of CTS buffers 1002a, equal in the number of stages of CTS buffers 1002a are connected to each other (shown by [8] in FIG. 12). Thereafter, in step 807d, sub-scan chains 1001 linked to each CTS buffer 1003a driving a plurality of CTS buffers 1002a are connected to each other so that connection be made from a sub-scan chain 1001 larger in the number of stages of CTS buffers 1002a to a sub-scan chain 1001 smaller in the number of stages (shown by [9] in FIG. 12). In step 807e, sub-scan chains 1001, among the sub-scan chains 1001 linked to a CTS buffer 1004a driving a plurality of CTS buffers 1003a, equal in the number of stages of CTS buffers 1003a are connected to each other (none applies in FIG. 12). And finally, in step 807f, sub-scan chains 1001 linked to the CTS buffer 1004a driving a plurality of CTS buffers 1003a are connected to each other so that connection be made from a sub-scan chain 1001 larger in the number of stages of CTS buffers 1003a to a sub-scan chain 1001 smaller in the number of stages (shown by [11] in FIG. 12).

Thereafter, referring back to FIG. 8, clock delay analysis is performed in step 808. In step 809, CTS adjustment (clock skew adjustment) is performed, and also optimization of partial placement and physical wiring is performed again under the mask layout CAD program. As a result, obtained are netlist data 810 and pattern information GDSII in which the shift register circuit portion has been reconfigured.

Thus, in the eighth embodiment, a design for testability (DFT) CAD program for implementing the scan test design described in the first to fourth and sixth embodiments can be provided.

### Ninth Embodiment

The ninth embodiment of the present invention will be described.

The ninth embodiment provides a DFT design CAD program for implementing the scan test design described in the first to fourth and sixth embodiments, and a mask layout CAD program having a function of optimizing scan chains. This will be described with reference to FIGS. 3 and 4.

In the scan insertion CAD program as a conventional DFT design program, FF circuits are replaced with scan FF circuits, and scan cascading is made randomly between shift data input terminals and output terminals of the scan FF circuits.

As shown in FIG. 4, in the scan insertion CAD program in the ninth embodiment, after RTL design, the logic synthesis CAD program 402 is executed for the RTL file 401 as the input data to generate the gate-level netlist 403. The scan test circuit insertion CAD program 404 is then executed for the gate-level netlist 403 to generate the scan test circuit inserted netlist 405. The details of the scan test circuit insertion CAD program 404 are as shown in FIG. 9 described above, and thus description thereof is omitted here.

Thereafter, in the step 406 shown in FIG. 4, wiring is made under the conventional mask layout CAD program, and CTS is inserted. In the step 407, clock delay analysis is performed. In the step 408, clock skew adjustment is performed based on the results of the clock delay analysis. Subsequently, information on connection between FF circuits on the scan shift side is temporarily cut, and part of netlist information is reset. Thereafter, a netlist is reconfigured with the algorithm described in the first to sixth embodiments based on the number of stages of CTS buffers and the number of stages of elements of the clock circuit or clock delay information on sub-scan chains, using the CAD program in the ninth embodiment. In the step 408, also, physical wiring is executed again for the new scan shift-side circuit under the mask layout CAD program, using the new gate-level netlist in which the scan shift-side circuit has been optimized. The scan chain optimization CAD program in the step 408 is substantially the same as the CAD program shown in FIG. 10, except that the point of execution of the program is after the clock skew adjustment performed based on the results of the clock delay analysis. Therefore, description on this program is omitted here.

As a result, the CAD program in the ninth embodiment outputs a netlist and mask layout data in which the shift circuit portion has been reconfigured.

### Tenth Embodiment

The tenth embodiment of the present invention will be described.

In the first embodiment, a scan shift register was formed from FF circuits driven with the same final-stage CTS element as the minimum unit. In the tenth embodiment, provided is a method in which a sub-scan chain is formed from FF circuits grouped by a net serving as the start point of execution of gated CTS and terminals as the minimum unit for a CTS-gating circuit.

As a method permitting implementation of a low-power circuit, a design method using clock gating is known. Some CAD tool has a function of automatically establishing CTS even when a gated circuit exists in a clock line. In this case, in principle, high-precision skew adjustment has often been made from the net as the start point of execution of gated CTS up to the clock terminals of FF circuits. Accordingly, in combining the present invention with such a design method, a sub-scan chain may be formed from FF circuits connected to the part of the clock tree downstream of the base point of execution of gated CTS as the minimum unit. The scan test design described above can also be applied to this case.

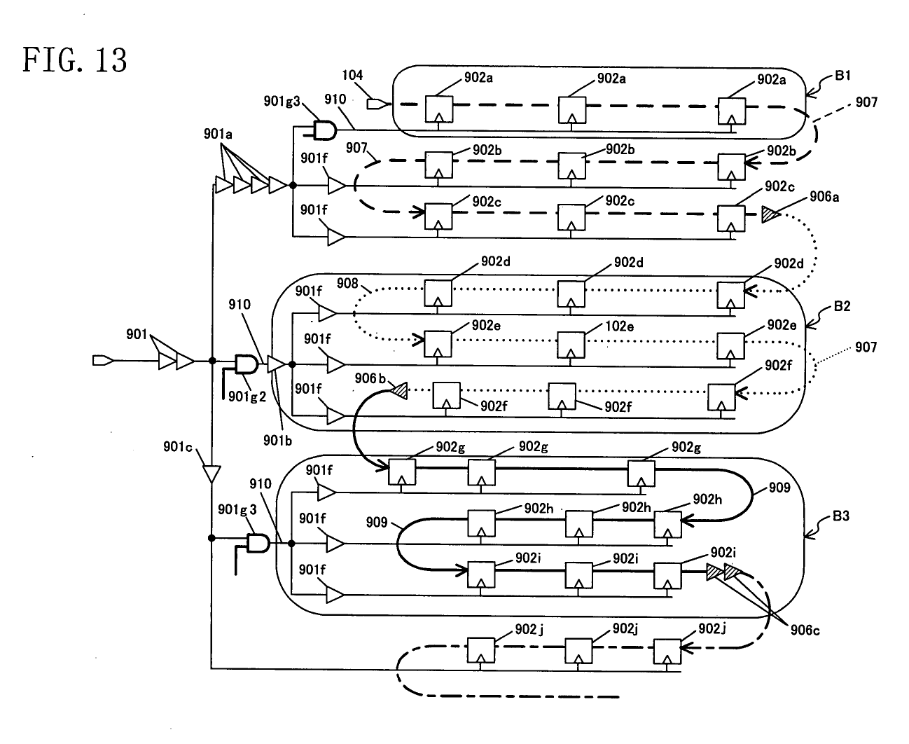

A method for forming a sub-scan chain with gated CTS described above will be described with reference to FIG. 13. Referring to FIG. 13, in a gated clock tree GS, first, second and third gating elements (clock gate elements) 901g1, 901g2 and 901g3 are placed. The first gating element 901g1 is connected to clock terminals of three scan flipflop circuits 902a belonging to a first block B1 on the top. The second gating element 901g2 is connected to clock terminals of nine scan flipflop circuits 902d, 902e and 902f belonging to a second block B2 in the middle. The third gating element 901g3 is connected to clock terminals of nine scan flipflop circuits 902g, 902h and 902i belonging to a third block B3 on the bottom. The gating elements 901g1 to 901g3 halt supply of the clock signal to the flipflop circuits belonging to the corresponding blocks B1 to B3 when a common or individual condition is satisfied, to thereby achieve low power.

Further, in the respective blocks B1 to B3, the flipflop circuits therein are placed at positions closer to one another so as to minimize power required for clock supply from the corresponding gating elements 901g1 to 901g3. Therefore,-the flipflop circuits belonging to the same block are roughly the same in the value of the propagation delay time of the clock signal from the corresponding gating element 90lg1, 901g2 or 901g3. In view of this, in this embodiment, the plurality of flipflop circuits belonging to the same block are connected in series, to thereby form one sub-scan shift register for each of the blocks B1 to B3.

In FIG. 13, the same connection method as that described in the second embodiment shown in FIG. 1 is adopted for connection between sub-scan shift registers in each of these blocks and between these sub-scan shift registers and sub-scan shift registers composed of other flipflop circuits.

In the case of gated CTS, portions equivalent in the number of stages of elements of the clock tree and in circuit configuration are few in number in not a few cases. Therefore, it is desirable to combine this method with the sixth embodiment in which scan chain optimization is attempted by use of the results of the clock delay analysis after CTS insertion.

The scan test circuits and the design methods thereof according to the present invention were described. Any of such scan test circuits may be put together with an internal circuit of which operation is tested with the scan test circuit, to form a large-scale integrated circuit, and further portable digital equipment having such a large-scale integrated circuit may be produced. Since the scan test circuit described above is a low-power circuit, a large-scale integrated circuit and digital equipment having a long battery life can be implemented.

### INDUSTRIAL APPLICABILITY

As described above, according to the present invention, design guarantee for the operation of a scan shift register can be easily secured, and the number of delay elements for hold guarantee inserted in a shift data transfer line can be reduced. Therefore, the present invention is applicable to scan test design methods, scan test circuits and scan test circuit insertion programs, which realize robust design permitting little design reversion, improvement in the convergence of the timing characteristic and satisfactory guarantee of the scan shift operation, and also to large-scale integrated circuits and the like provided with such scan test circuits, used for portable digital equipment and the like.

1. A scan test design method, wherein in a semiconductor integrated circuit having a number of scan flipflop circuits as a scan test circuit, with a clock tree being formed for clock terminals of the scan flipflop circuits,
attention is paid to a plurality of final-stage elements located at the final stage of the clock tree, and a plurality of scan flipflop circuits driven with each of the final-stage elements are connected in series, to form a scan shift register for each final-stage element.

2. The scan test design method of claim 1, wherein the scan shift register for each of the final-stage elements is regarded as a sub-scan chain, and in connecting such sub-scan chains to each other to form a longer scan shift register,
priority is given to connection between sub-scan chains equal in the number of stages of elements constituting the clock tree.

3. The scan test design method of claim 1, wherein the scan shift register for each of the final-stage elements is regarded as a sub-scan chain, and in connecting such sub-scan chains to each other to form a longer scan shift register,
priority is given to connection between sub-scan chains smallest in a relative difference in the number of stages of elements constituting the clock tree when sub-scan chains different in the number of stages of elements constituting the clock tree are to be connected to each other.

4. The scan test design method of claim 3, wherein when sub-scan chains different in the number of stages of elements constituting the clock tree are connected to each other,
a delay element of the number determined in advance according to the difference in the number of stages of elements constituting the clock tree is inserted between the sub-scan chains connected to each other.

5. The scan test design method of claim 1, 2, 3 or 4, wherein the scan shift register for each of the final-stage elements is regarded as a sub-scan chain, and in connecting such sub-scan chains to each other to form a longer scan shift register,
the sub-scan chains are connected so that data transfer be made from a sub-scan chain longer in a delay time from a clock origin point of the clock tree up to the clock terminals of the flipflop circuits constituting the sub-scan chain to a sub-scan chain shorter in the delay time.

6. A scan test design method, wherein in a semiconductor integrated circuit having a number of scan flipflop circuits as a scan test circuit, with a clock tree being formed for clock terminals of the scan flipflop circuits,
the semiconductor integrated circuit also having a gated clock tree with clock gate elements placed at a plurality of predetermined positions of the clock tree,
attention is paid to the plurality of clock gate elements, and a plurality of scan flipflops driven with each of the clock gate elements are connected in series, to form a scan shift register for each clock gate element.

7. The scan test design method of claim 6, wherein the scan shift register for each of the final-stage elements is regarded as a sub-scan chain, and in connecting such sub-scan chains to each other to form a longer scan shift register,
the scan test design method of claim 2, 3, 4 or 5 is executed.

8. A scan test circuit comprising a scan shift register having a plurality of scan flipflop circuits connected in series, with a clock tree being formed for clock terminals of the plurality of scan flipflop circuits,
wherein at least two flipflop circuits equal in the number of stages of elements of the clock tree from a predetermined clock supply point of the clock tree up to the clock terminals of the flipflop circuits, among the plurality of scan flipflop circuits, are connected to each other sequentially, to form the scan shift register.

9. The scan test circuit of claim 8, wherein as for flipflop circuits different in the number of stages of elements of the clock tree from the predetermined clock supply point of the clock tree up to the clock terminals of the flipflop circuits,
flipflop circuits smallest in a relative difference in the number of stages of elements of the clock tree from the predetermined clock supply point of the clock tree up to the clock terminals of the flipflop circuits are connected to each other sequentially, to make the scan shift register longer.

10. A scan test circuit having a plurality of scan flipflop circuits, with a clock tree being formed for clock terminals of the plurality of scan flipflop circuits,
wherein for each of a plurality of final-stage elements located at the tail ends of the clock tree, a scan shift register is formed from a plurality of flipflop circuits connected to the final-stage element.

11. The scan test circuit of claim 8, wherein delay elements are placed between the scan shift registers, and
the scan shifter registers are connected to each other via the delay elements to form a long shift register.

12. The scan test circuit of claim 11, each of the delay circuits is composed of a transistor having a threshold voltage higher than a threshold voltage of transistors constituting the flipflop circuits.

13. A scan test circuit insertion CAD program, for a semiconductor integrated circuit having a number of flipflop circuits, with a clock tree being formed for clock terminals of the flipflop circuits, the program allowing a computer to execute the steps of:
replacing the flipflop circuits with scan flipflop circuits; and
connecting a plurality of flipflop circuits driven with each of a plurality of final-stage elements located at the final stage of the clock tree in series to form a scan shift register.

14. a scan test circuit insertion CAD program allowing a computer to execute the steps of:
entering circuit data for a given scan test circuit having a plurality of scan flipflop circuits;
temporarily cutting circuit connection in a shift data transfer portion between the scan flipflop circuits in the circuit data;
thereafter, connecting in series a plurality of scan flipflop circuits driven with each of a plurality of final-stage elements located at the final stage of a clock tree, when such a clock tree is formed for clock terminals of the plurality of scan flipflop circuits, to form a scan shift register to thereby optimize a scan chain; and
outputting netlist information after the optimization.

15. The scan test circuit insertion program of claim 14, wherein when the scan shift register obtained by connecting a plurality of scan flipflop circuits driven with each of the final-stage elements in series is regarded as a sub-scan chain and such sub-scan chains different in the number of stages of elements constituting the clock tree are connected to each other, the program allows a computer to execute the steps of:
giving priority to connection between sub-scan chains smallest in a relative difference in the number of stages of elements constituting the clock tree; and
thereafter outputting netlist information.

16. A large-scale integrated circuit comprising:
the scan test circuit of claim 8, 9 or 10; and
an internal circuit to be tested by the scan test circuit.

17. Portable digital equipment incorporating the large-scale integrated circuit of claim 16.
